(19) United States
(12) Patent Application Publication
(10) Pub. No.: US 2007/0007533 A1
(43) Pub. Date: Jan. 11, 2007

(54) PIXEL ARRAY STRCUTURE

(76) Inventors: Yi-Tyng Wu, Chiayi (TW); Tsuan-Lun Lung, Hsinchu City (TW); Chih-Hung Cheng, Hsinchu County (TW); Kuan-Te Pai, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/160,775

(22) Filed: Jul. 8, 2005

(51) Int. Cl. H01L 29/08

(52) U.S. Cl. 257/72

(57) ABSTRACT

A pixel array structure is provided. The pixel array structure comprises a plurality of pixel units and a plurality of dielectric walls. Each dielectric wall is disposed between two neighboring pixel units, wherein each pixel unit comprises at least one organic light emitting diode and a complementary metal-oxide-semiconductor (CMOS). The organic light emitting diode comprises a transparent electrode, a bottom electrode, and a light emitting material between the transparent electrode and the bottom electrode. The CMOS is disposed in a substrate. The substrate comprises a top-metal-layer structure located thereon and the top-metal-layer structure comprises an upmost top metal layer. Further, the bottom electrode of the CMOS is the upmost top metal layer of the top-metal-layer structure and the upmost top metal layer is a titanium metal layer.

### BACKGROUND OF THE INVENTION

1. Field of the Invention

The present invention relates to a display device structure, and more particularly to a pixel structure.

2. Description of Related Art

In order to accord with diversified information equipment, flat panel displays (FPDs) have become essentially required apparatuses. To meet the future trend of displays being slim and power-saving, flat panel displays have gradually replaced cathode ray tube (CRT) displays. At present, applications of FPD technology can be categorized as follows: plasma displays, liquid crystal displays, electroluminescent displays, light emitting diode (LED) displays, vacuum fluorescent displays, field emission displays, electrochromic displays, and organic light emitting diode (OLED) displays.

An OLED display comprises the following advantages: (1) no restriction of view angles; (2) low manufacturing cost; (3) high responsive speed (hundreds' times faster than that of a liquid crystal display); (4) low power consumption; (5) application in portable devices with direct-current (DC) driving; (6) application within wide temperature range; and (7) slimness, and minimization accommodated with hardware. Accordingly, an OLED display has met the requirement of the multi-medium display. Therefore, among the various panel displays, OLED displays have potential to be the next-generation panel displays.

However, the life time of an OLED display depends on the life time of its light emitting material. Accordingly, how to extend the life time of the light emitting material is the key issue in enhancing the life time of the OLED display.

Additionally, the light emitting material normally is in liquid state when being filled in. The light emitting material is likely to penetrate into the top metal layer between the pixel units which may cause the area between the pixels to slightly illuminate due to the existence of the light emitting material. As a result, illumination of the OLED display will not be uniform.

### SUMMARY OF THE INVENTION

Accordingly, the present invention is directed to a pixel structure. The bottom electrode of the organic light emitting diode of the structure is a titanium metal layer. The titanium metal effectively delays the decay of the light emitting material of the organic light emitting diode and enhances the life time of the organic light emitting diode (OLED) display.

The present invention is also directed to a pixel array structure. In this structure, the dielectric walls are used to isolate organic light emitting diodes and prevent the penetration of the light emitting material between the pixel units. Accordingly, the OLED display uniformly illuminates.

The present invention provides a pixel structure. The structure comprises an organic light emitting diode and a complementary metal-oxide-semiconductor (CMOS). Wherein, the organic light emitting diode comprises a transparent electrode, a bottom electrode, and a light emitting material between the transparent electrode and the bottom electrode. The CMOS is in a substrate. The substrate comprises a top-metal-layer structure thereon. The top-metal-layer structure comprises a titanium metal layer as an upmost top metal layer. The bottom electrode of the organic light emitting diode is the upmost top metal layer, and the CMOS controls the light emitting diode through the upmost top metal layer.

The present invention provides a pixel array structure. The structure comprises a plurality of pixel units and a plurality of dielectric walls. Each dielectric wall is disposed between two neighboring pixel units. Wherein, each pixel unit comprises an organic light emitting diode and a complementary metal-oxide-semiconductor (CMOS). The organic light emitting diode comprises a transparent electrode, a bottom electrode, and a light emitting material between the transparent electrode and the bottom electrode. The CMOS is in a substrate. The substrate comprises a top-metal-layer structure thereon. The top-metal-layer structure comprises an upmost top metal layer. The upmost top metal layer is a titanium metal layer. The bottom electrode of the organic light emitting diode is the upmost top metal layer of the top-metal-layer structure. The CMOS controls the light emitting diode through the upmost top metal layer.

According to the pixel array structure of a preferred embodiment of the present invention, a top surface of each dielectric wall co-planarizes with a top surface of each upmost top metal layer, for example.

According to the pixel array structure of a preferred embodiment of the present invention, a top surface of each dielectric wall is higher than a top surface of each upmost top metal layer, for example.

According to the pixel array structure of a preferred embodiment of the present invention, a top of each dielectric wall comprises a T-shape structure. The T-shape structure extends along a direction toward to each pixel unit adjacent to the dielectric wall, and partially covers each of the upmost top metal layers.

According to the pixel array structure of a preferred embodiment of the present invention, a top surface of each dielectric wall is higher than the top-metal-layer structure, for example.

According to the pixel structure of the pixel array structure of a preferred embodiment of the present invention, a material of the transparent electrode can be, for example, indium-zinc oxide or indium-tin oxide.

According to the pixel structure or the pixel array structure of a preferred embodiment of the present invention, the light emitting material can be, for example, an organic light emitting material or a polymer light emitting material.

According to the pixel structure or the pixel array structure of a preferred embodiment of the present invention, the thickness of the upmost top metal layer is from 300 Å to 3000 Å.

In the present invention, the titanium metal layer serves as the upmost top metal layer of the top-metal-layer structure of the CMOS, and the upmost top metal layer serves as the bottom electrode of the organic light emitting diode. Accordingly, the decay of the organic light emitting diode can be efficiently delayed, and the life time of the OLED display can be enhanced. In addition, the CMOS of the substrate controls the illumination of the organic light emitting diode through the upmost top metal layer of the top-metal-layer structure, serving as a switch of the organic light emitting diode.

In this invention, the dielectric walls are used to isolate pixel units from each other and prevent the penetration of the light emitting material between the pixel units. Accordingly, the slight illumination between the pixel units caused by the light emitting material can be eliminated, and the OLED display uniformly illuminates.

The above and other features of the present invention will be better understood from the following detailed description of the preferred embodiments of the invention that is provided in communication with the accompanying drawings.

### BRIEF DESCRIPTION OF THE DRAWINGS

While the specification concludes with claims particularly pointing out and distinctly claiming the subject matter which is regarded as the invention, the objects and features of the invention and further objects, features and advantages thereof will be better understood from the following description taken in connection with the accompanying drawings.

FIG. 1 is a cross sectional view of a pixel structure according to a preferred embodiment of the present invention.

FIG. 2A is a top view of a pixel array structure according to a preferred embodiment of the present invention.

FIG. 2B is a schematic cross sectional view of the structure of FIG. 2A.

FIG. 3 is a cross sectional view of dielectric walls of a pixel array according to another preferred embodiment of the present invention.

FIG. 4 is a cross sectional view of dielectric walls of a pixel array according to another preferred embodiment of the present invention.

### DESCRIPTION OF THE PREFERRED EMBODIMENT

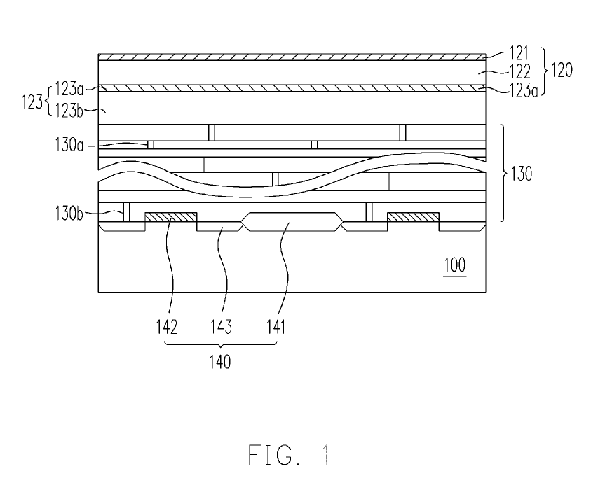

FIG. 1 is a cross sectional view of a pixel structure according to a preferred embodiment of the present invention. Referring to FIG. 1, according to the pixel structure of the preferred embodiment of the present invention, the structure comprises an organic light emitting diode (OLED) 120, and a complementary metal-oxide-semiconductor (CMOS)

140. Wherein, the OLED 120 comprises a transparent electrode 121, a bottom electrode 123a, and a light emitting material 122 between the transparent electrode 121 and the bottom electrode 123a. The material of the transparent electrode 121 can be, for example, indium-zinc oxide, or indium-tin oxide. The light emitting material 122 can be, for example, an organic light emitting material, or a polymer light emitting material. The CMOS 140 comprises a field oxide layer 141, a gate 142, and source/drain regions 143 adjacent to two sides of the gate 142. Additionally, the CMOS 140 is disposed in a substrate 100. The substrate 100 can be, for example, a silicon substrate. The substrate 100 comprises a top-metal-layer structure 123 and a multi-layer structure 130 thereon. The top-metal-layer structure 123 comprises a titanium metal layer as an upmost top metal layer 123a. The top-metal-layer structure 123 also comprises a metal-stack layer 123b and an upmost top metal layer 123a. The upmost top metal layer 123a also is the bottom electrode 123a of the OLED 120. The upmost top metal layer 123a is the titanium metal layer, which has a thickness of about 300-3000 Å. The multi-layer structure 130 comprises, for example, inter-metal dielectric layers, TiN layers, or metal layers. The metal layers electrically connect with each other through vias 130a, or with source/drain regions 143 through contact plugs 130b. Accordingly, the OLED 120 electrically connects with the CMOS 140 through the upmost top metal layer 123a, i.e., the bottom electrode of the OLED 120. The CMOS 140 thus controls the OLED 120 through the upmost top metal layer 123a.

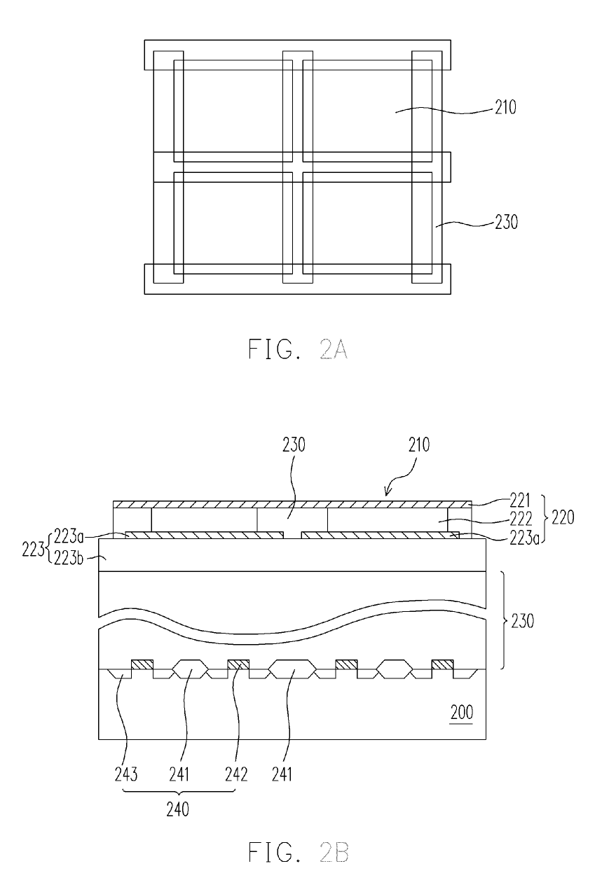

FIG. 2A is a top view of a pixel array structure according to a preferred embodiment of the present invention. FIG. 2B is a schematic cross sectional view of the structure of FIG. 2A. Referring to FIGS. 2A and 2B, according to the pixel array structure of the preferred embodiment of the present invention, the structure comprises a plurality of pixel units 210 and a plurality of dielectric walls 230. Each dielectric wall 230 is disposed between two neighboring pixel units 210. Wherein, a top of each dielectric wall 230 comprises a T-shape structure. The T-shape structure extends along a direction toward to each pixel unit 210 adjacent to the dielectric wall 230, and partially covers each upmost top metal layer 223a, i.e., the bottom electrodes 223a of the OLED 220 as shown in FIG. 2B. Additionally, each pixel unit 210 comprises an organic light emitting diode (OLED) 220, and a complementary metal-oxide-semiconductor (CMOS) 240. Wherein, the OLED 120 comprises a transparent electrode 221, a bottom electrode 223a, and a light emitting material 222 between the transparent electrode 221 and the bottom electrode 223a. The material of the transparent electrode 221 can be, for example, indium-zinc oxide, or indium-tin oxide. The light emitting material can be, for example, an organic light emitting material, or a polymer light emitting material. The CMOS 240 comprises a field oxide layer 241, a gate 242, and source/drain regions 243 adjacent to two sides of the gate 242.

Additionally, the CMOS 240 is disposed in a substrate 200. The substrate 200 can be, for example, a silicon substrate. The substrate 200 comprises a top-metal-layer structure 223 and a multi-layer structure 230 formed thereon, wherein the top-metal-layer structure 223 comprises an upmost top metal layer 223a. The top-metal-layer structure 223 comprises a titanium metal layer as the upmost top metal layer 223a. The top-metal-layer structure 223 also comprises a metal-stack layer 223b. The upmost top metal layer 223a also is the bottom electrode 223a of the OLED 220. The upmost top metal layer 223a is the titanium metal layer, which has a thickness of about 300-3000 Å. Accordingly, the OLED 220 electrically connects with the CMOS 240 through the upmost top metal layer 223a, i.e., the bottom electrode of the OLED 220. The CMOS 240 thus controls the OLED 220 through the upmost top metal layer 223a.

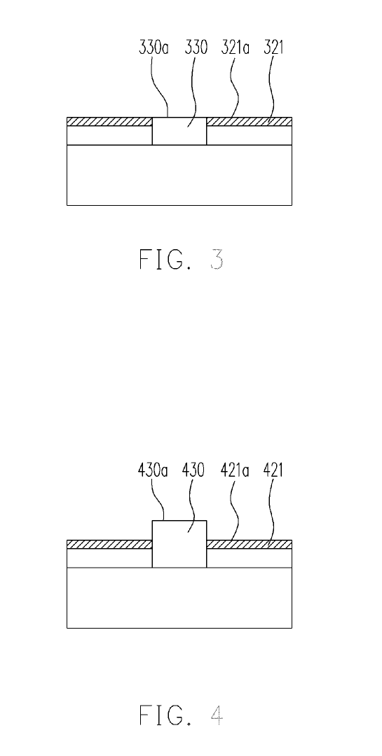

FIGS. 3 and 4 are cross sectional views of dielectric walls of a pixel array according to another preferred embodiment of the present invention. Referring to FIG. 3, according to the dielectric walls of the pixel array structure of the preferred embodiment of the present invention, a top surface 330a of each dielectric wall 330 co-planarizes with a top surface 321a of each upmost top metal layer 321, i.e., the bottom electrode 321, for example. Referring to FIG. 4, according to the dielectric walls of the pixel array structure of the preferred embodiment of the present invention, a top surface 430a of each dielectric wall 430 is higher than a top surface 421a of each upmost top metal layer 421, i.e., the bottom electrode 421, for example.

In summary, the pixel structure and the pixel array structure have at least the following advantages.

1. In the present invention, the titanium metal layer serves as the upmost top metal layer of the top-metal-layer structure of the CMOS, and the upmost top metal layer serves as the bottom electrode of the organic light emitting diode. Accordingly, the decay of the organic light emitting diode can be efficiently delayed, and the lifetime of the OLED display can be enhanced.

2. In this invention, the dielectric walls are used to isolate pixel units from each other and prevent the penetration of the light emitting material between the pixel units. Accordingly, the slight illumination between the pixel units caused by the light emitting material can be eliminated, and thus the OLED display can uniformly illuminate.

3. In addition, the CMOS of the substrate controls the illumination of the organic light emitting diode through the upmost top metal layer of the top-metal-layer structure, serving as a switch of the organic light emitting diode. [Para 36]Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

What is claimed is:

1. A pixel structure, comprising:
an organic light emitting diode, the organic light emitting diode comprising a transparent electrode, a bottom electrode, and a light emitting material between the transparent electrode and the bottom electrode; and
a complementary metal-oxide-semiconductor (CMOS) in a substrate, wherein the substrate comprises a top-metal-layer structure located thereon, the top-metal-layer structure comprises a titanium metal layer as an upmost top metal layer, the bottom electrode is the upmost top metal layer, and the CMOS controls the light emitting diode through the upmost top metal layer.

2. The pixel structure of claim 1, wherein a material of the transparent electrode comprises indium-zinc oxide or indium-tin oxide.

3. The pixel structure of claim 1, wherein the light emitting material comprises an organic light emitting material or a polymer light emitting material.

4. The pixel structure of claim 1, wherein a thickness of the upmost top metal layer is from 300 Å to 3000 Å.

5. A pixel array structure, comprising:
a plurality of pixel units; and
a plurality of dielectric walls, wherein each dielectric wall is disposed between two adjacent pixel units.

6. The pixel array structure of claim 5, wherein each of the pixel units comprises:
an organic light emitting diode, wherein the organic light emitting diode comprising a transparent electrode, a bottom electrode, and a light emitting material between the transparent electrode and the bottom electrode; and
a complementary metal-oxide-semiconductor (CMOS) in a substrate, wherein the substrate comprises a top-metal-layer structure located thereon, the top-metal-layer structure comprises an upmost top metal layer, the bottom electrode is the upmost top metal layer, and the CMOS controls the light emitting diode through the upmost top metal layer.

7. The pixel array structure of claim 6, wherein the upmost top metal layer is a titanium metal layer.

8. The pixel array structure of claim 6, wherein a material of the transparent electrode comprises indium-zinc oxide or indium-tin oxide.

9. The pixel array structure of claim 6, wherein the light emitting material comprises an organic light emitting material or a polymer light emitting material.

10. The pixel array structure of claim 6, wherein a top surface of each dielectric wall co-planarizes with a top surface of the bottom electrode of each pixel unit.

11. The pixel array structure of claim 6, wherein a top surface of each dielectric wall is higher than a top surface of the bottom electrode of each pixel unit.

12. The pixel array structure of claim 6, wherein a top of each dielectric wall comprises a T-shape structure, the T-shape structure extends along a direction toward to each pixel unit adjacent to the dielectric wall, and partially covers the bottom electrode of each pixel unit.

13. The pixel array structure of claim 6, wherein a thickness of the upmost top metal layer is from 300 Å to 3000 Å.
